(19) United States
(12) Patent Application Publication
(10) Pub. No.: US 2026/0170637 A1
(43) Pub. Date: Jun. 18, 2026

(54) METHOD, SYSTEM, DEVICE, AND STORAGE MEDIUM FOR MEASURING REMAINING SILICON THICKNESS

(71) Applicant: Shenzhen Technology University, Shenzhen (CN)

(72) Inventors: Gengliang CHEN, Shenzhen (CN); Renjie GUI, Shenzhen (CN); Yu ZHONG, Shenzhen (CN); Songhua XIE, Shenzhen (CN); Haozheng LI, Shenzhen (CN)

(73) Assignee: Shenzhen Technology University, Shenzhen (CN)

(21) Appl. No.: 19/349,215

(22) Filed: Oct. 3, 2025

(30) Foreign Application Priority Data
Dec. 18, 2024 (CN) 2024118649091

(51) Int. Cl. G06T 7/00; G01B 11/06; G06T 7/60; H01L 21/66

(52) U.S. Cl. CPC G06T 7/001; G01B 11/06; G06T 7/60; H10P 74/203; G06T 2207/10056; G06T 2207/30148; G06T 2207/30168

(57) ABSTRACT

A method and system for measuring remaining silicon thickness, a device, and a storage medium are disclosed. According to the method, a sample image set is acquired by changing a distance between an objective lens and a sample, sharpness evaluation is performed on the sample image set, and corresponding sharp images are obtained by screening using a preset condition based on the sharpness evaluation value dataset; and finally, a remaining silicon thickness measurement result can be quickly obtained with high precision through calculation according to the sharp images, objective lens positions corresponding to the sharp images, and a preset algorithm.

### CROSS-REFERENCE TO RELATED APPLICATION

This application is based on and claims the benefit of priority from Chinese Patent Application No. 2024118649091, filed on 18 Dec. 2024, the entirety of which is incorporated by reference herein.

### TECHNICAL FIELD

The present disclosure relates to measurement techniques, and in particular to a method, system and apparatus for measuring remaining silicon thickness, and a storage medium.

### BACKGROUND

Through-Silicon Via (TSV) technology originated from the demand for miniaturization and high integration of semiconductor devices. With the advancement of Moore's Law, conventional two-dimensional packaging technologies can no longer meet the increasing requirements on integration, so the TSV technology has been developed. According to the TSV technology, three-dimensional interconnection between chips is achieved by forming vertical vias inside the chips, thereby greatly improving the integration and packaging efficiency of electronic components.

In practical applications of the TSV technology, wafer backside thinning is an important process step. The thinning of the backside of the wafer can reduce the package mounting height and the chip package volume, improve the thermal diffusion efficiency and electrical performance of the chip, and so on. During the wafer backside thinning process, the remaining silicon thickness (RST) of the wafer needs to be precisely measured to ensure that the thinned wafer meets design requirements and quality standards. However, methods commonly used for measuring the remaining silicon thickness still have disadvantages. For example, the measurement of the remaining silicon thickness using an x-ray microscope has high requirements on the operating environment, and is easily affected by the operating environment, resulting in low measurement efficiency. The acoustic measurement of the remaining silicon thickness has high requirements on the operating environment and is inefficient. To sum up, the techniques for measuring the remaining silicon thickness in conventional technologies have the disadvantages of low measurement precision and low measurement efficiency.

### SUMMARY

Therefore, to address one of the above problems, an objective of embodiments of the present disclosure is to provide a method, system and device for measuring remaining silicon thickness, and a storage medium, to effectively improve the precision and efficiency of measurement of the remaining silicon thickness.

In accordance with an aspect of the present disclosure, an embodiment provides a method for measuring remaining silicon thickness, including:
acquiring a sample image set by changing a distance between an objective lens and a sample, where the sample image set is formed by light converged onto the sample after passing through the objective lens and a rough-surface silicon wafer in sequence and reflected by the sample to pass through the rough-surface silicon wafer, the objective lens, and an imaging lens in sequence; and the sample includes a smooth surface wafer having one or more cylindrical hole;
determining a plurality of sharp images in the sample image set whose sharpness satisfies a preset condition and objective lens positions corresponding to the plurality of sharp images; and
calculating a remaining silicon thickness of the sample based on the plurality of sharp images, the objective lens positions corresponding to the plurality of sharp images, and a preset algorithm.

Further, the determining a plurality of sharp images in the sample image set whose sharpness satisfies a preset condition and objective lens positions corresponding to the plurality of sharp images includes:
calculating a sharpness evaluation value dataset based on the sample image set and a sharpness evaluation function;
acquiring the plurality of sharp images whose sharpness satisfies the preset condition based on the sharpness evaluation value dataset and the preset condition, where the plurality of sharp images whose sharpness satisfies the preset condition includes a sharp image of a bottom of the cylindrical hole of the smooth surface wafer, a sharp image of the rough-surface silicon wafer, and a sharp image of a reflected virtual image of the rough-surface silicon wafer; and
acquiring the corresponding objective lens positions based on the plurality of sharp images.

Further, the acquiring the plurality of sharp images whose sharpness satisfies the preset condition based on the sharpness evaluation value dataset and the preset condition includes:
acquiring a plurality of sharpness evaluation maxima based on the sharpness evaluation value dataset; and
acquiring the plurality of sharp images based on the plurality of sharpness evaluation maxima.

Further, the calculating a remaining silicon thickness of the sample based on the plurality of sharp images, the objective lens positions corresponding to the plurality of sharp images, and a preset algorithm includes:
acquiring a thickness value of the rough-surface silicon wafer; and
calculating the remaining silicon thickness of the sample based on the objective lens position corresponding to the sharp image of the bottom of the cylindrical hole of the smooth surface wafer, the objective lens position corresponding to the sharp image of the rough-surface silicon wafer, the objective lens position corresponding to the sharp image of the reflected virtual image of the rough-surface silicon wafer, the thickness value, and the preset algorithm.

Further, the preset algorithm includes:

$$Hrst = ( h 2 + h 1 - d ) / 2 - h t$$

where Hrst is the remaining silicon thickness of the sample, h1 is the objective lens position corresponding to the sharp image of the rough-surface silicon wafer, h2 is the objective lens position corresponding to the sharp image of the reflected virtual image of the rough-surface silicon wafer, d is the thickness value, and ht is the objective lens position corresponding to the sharp image of the bottom of the cylindrical hole of the smooth surface wafer.

In accordance with another aspect of the present disclosure, an embodiment provides a system for measuring remaining silicon thickness, including a camera, a lens cavity, a light source, a rough-surface silicon wafer, a leveling device, a platform, a column, a movable guide rail, and a processor, where:
the platform is configured for fixing the column and the leveling device;
the leveling device is configured for loading a sample;
the column is configured for fixing the movable guide rail;
the movable guide rail is configured for fixing the lens cavity;
the lens cavity includes an aperture stop, a collimating lens unit, a beam splitter, an objective lens, and an imaging lens;
the processor is configured for implementing the method in accordance with the first aspect;
light emitted by the light source passes through the aperture stop, a first collimating lens, a second collimating lens, and the beam splitter in sequence; and the light deflected by the beam splitter passes through the objective lens, the rough-surface silicon wafer, and the sample in sequence, and is reflected by the sample to pass through the rough-surface silicon wafer, the objective lens, the beam splitter, and the imaging lens in sequence and finally enter the camera.

Further, the light source is a broadband source including both silicon-transmissive and silicon-non-transmissive spectral bands.

Further, the rough-surface silicon wafer includes a grid pattern, the grid pattern including bar, square and circular shapes.

In accordance with another aspect of the present disclosure, an embodiment provides a device for measuring remaining silicon thickness, including:
at least one processor; and
at least one memory, configured for storing at least one program,
where the at least one program, when executed by the at least one processor, causes the at least processor to implement the method described above.

In accordance with another aspect of the present disclosure, an embodiment provides a computer-readable storage medium, having a processor-executable program stored therein, where the processor-executable program, when executed by a processor, causes the processor to implement the method described above.

In view of the above, the embodiments of the present disclosure can achieve the following beneficial effects.

The present disclosure provides a method, system and device for measuring the remaining silicon thickness, and a storage medium. According to the method, a sample image set is acquired by changing a distance between an objective lens and a sample, sharpness evaluation is performed on the sample image set, and corresponding sharp images are obtained by screening using a preset condition based on the sharpness evaluation value dataset; and finally, a remaining silicon thickness measurement result can be quickly obtained with high precision through calculation according to the sharp images, objective lens positions corresponding to the sharp images, and a preset algorithm. In addition, according to a self-made rough-surface silicon wafer and objective lens positions corresponding to imaging of the rough-surface silicon wafer, the objective lens position corresponding to the surface of the smooth surface wafer can be measured, such that the remaining silicon thickness of the smooth surface wafer can be measured, and the precision of measurement of the remaining silicon thickness of the wafer can be further improved. Therefore, the system for measuring remaining silicon thickness provided by the present disclosure can effectively improve the precision and efficiency of measurement of the remaining silicon thickness.

### BRIEF DESCRIPTION OF DRAWINGS

FIG. 1 is a schematic flowchart of a method for measuring remaining silicon thickness according to an embodiment of the present disclosure;

FIG. 2 is a structural block diagram of a system for measuring remaining silicon thickness according to an embodiment of the present disclosure;

FIG. 3 is a schematic flowchart of another method for measuring remaining silicon thickness according to an embodiment of the present disclosure;

FIG. 4 is a schematic diagram showing a position of a virtual image of the rough-surface silicon wafer in the method according to an embodiment of the present disclosure;

FIG. 5 is another schematic diagram showing a position of a virtual image of the rough-surface silicon wafer in the method according to an embodiment of the present disclosure;

FIG. 6 is another schematic diagram showing a position of a virtual image of the rough-surface silicon wafer in the method according to an embodiment of the present disclosure; and

FIG. 7 is a structural block diagram of a storage medium according to an embodiment of the present disclosure.
Reference numerals: 1—broadband light source, 2—aperture stop, 3—first collimating lens, 4—second collimating lens, 5—camera, 6—imaging lens, 7—beam splitter, 8—objective lens, 9—rough-surface silicon wafer, 10—sample, 11—leveling device, 12—platform, 13—movable guide rail, 14—column, 15—lens cavity, 21—rough-surface silicon wafer, 22—reflected virtual image of rough-surface silicon wafer, d—thickness of rough-surface silicon wafer, h1—objective lens position corresponding to image of self-made silicon wafer, h2—objective lens position corresponding to sharp image of reflected virtual image of rough-surface silicon wafer, h3—objective lens position corresponding to the smooth surface of sample wafer, htx-objective lens position corresponding to bottom of cylindrical hole (x=1, 2, 3, . . . ).

### DETAILED DESCRIPTION

The present disclosure is further described below in conjunction with the accompanying drawings and specific embodiments. The step numbers in the following embodiments are set only for convenience of description and are not intended to limit the order of the steps in any way, and the execution order of the steps in the embodiments can be adaptively adjusted according to the understanding of those having ordinary skills in the art.

Related technologies involved in the present disclosure will be described below.

Measurement using a laser scanning confocal microscope: The laser scanning confocal microscope measures the inner wall of TSVs and the remaining silicon thickness by detecting a reflected light signal to provide high-resolution depth information. This method has the advantage of non-contact measurement, and is suitable for in-line monitoring during wafer fabrication. In this method, the measurement is generally performed from the front side to capture features of the surface of the TSVs. However, as the TSV aspect ratio increases, the reflected light signal attenuates seriously, and the scattering effect becomes significant when the TSV diameter is small, resulting in a significant decrease in measurement precision.

Measurement using an X-ray microscope: The X-ray microscope can acquire precise depth information in TSVs with a high aspect ratio by penetrating the TSV structure with X rays. In this method, the measurement can be performed from either the front or back side with high spatial resolution, and imaging of the inner and outer walls of TSVs can be realized. However, the X-ray microscope requires high equipment costs and complicated operation, is not suitable for large-scale detection in production lines, and has high requirements on operation personnel.

Acoustic measurement: Acoustic measurement uses the propagation characteristics of ultrasonic waves in silicon materials to measure the TSV depth and the remaining silicon thickness by analyzing the reflected signals. Ultrasonic waves can penetrate the material and acquire internal structural information of the material, but for TSVs with a high aspect ratio, signal attenuation and multiple reflections affect the accuracy and reliability of measurement. Acoustic measurement can be performed from either the front or back side, but is not suitable for use in mass production due to complicated equipment and environmental requirements.

Electrical measurement: In the electrical measurement method, an electrical signal is applied on the TSV to measure resistance, capacitance, and other properties of the TSV, which are used to derive the remaining silicon thickness. This method is generally performed from the front side. Although this method is practical to some extent, its measurement precision depends on the material properties of the TSV, making it difficult to ensure high precision in all scenarios, especially for TSV structures with significant variations in material properties.

Several terms involved in the present disclosure will be explained below.

Through-Silicon Via (TSV): It is a revolutionary semiconductor packaging and interconnection scheme. In this scheme, vertical conductive channels are directly formed inside the chip to realize high-speed, low-loss electrical connections between chips or between different layers inside the chip, thereby significantly improving the data transmission rate and system performance. The TSV technology is widely used in high-performance computing, 3D integrated circuits, large-capacity memory stacking, and other fields, and is one of the indispensable and important technologies in modern electronic industry.

Remaining Silicon Thickness (RST): It is the thickness of the silicon material layer remaining on the silicon wafer after a series of steps including etching, grinding, or polishing in the semiconductor manufacturing process. This parameter is crucial to the performance and reliability of the device, affecting the electrical conductivity, thermal conduction efficiency, and mechanical strength of the circuit. The precise control of the remaining silicon thickness can optimize the electrical and thermal properties of the device and improve the integration and operating frequency of integrated circuits, and is an indispensable part of semiconductor process.

Aspect ratio: It is the ratio between the depth of the silicon structure after etching or processing and a lateral dimension (e.g., diameter or width) of the silicon structure. This parameter is of great significance for evaluating the machining precision, structural stability, and performance of the silicon wafer. The measurement of the aspect ratio allows for a more comprehensive understanding of the distribution of remaining silicon thickness, providing an important basis for subsequent process control and optimization.

Scattering effect: In the measurement of the remaining silicon thickness, the scattering effect means that when a light beam (e.g., laser) is incident on the surface of a silicon wafer, some light rays will be scattered. The distribution of directions and intensities of these scattered light rays is closely related to the surface morphology, roughness, remaining silicon thickness, and other parameters of the silicon wafer. By analyzing the characteristics of the scattered light rays, the remaining silicon thickness can be indirectly calculated, which provides an important basis for processing and quality control of the silicon wafer.

Sharpness evaluation function: In the measurement of the remaining silicon thickness, the sharpness of an image or video is determined by comprehensively evaluating the acutance, resolution, contrast, noise, and the like of the edge of the image or video, thereby indirectly reflecting the thickness information of the silicon wafer and providing an important reference for high-precision measurement of the thickness of the silicon wafer. A sharpness evaluation function that can be used in the method for measuring remaining silicon thickness according to the present disclosure is provided below, where x and y represent coordinates of a pixel in an image:

Sharpness evaluation function: The gradient magnitude of each pixel is determined by calculating the sum of squares of grayscale differences between adjacent pixels in the x-axis and y-axis directions. Gradient values of all pixels are accumulated to obtain a final sharpness evaluation result of the image.

$$F = {\sum }_{x} {\sum }_{y} \{ {[ f ( x + 1 , y ) - f ( x , y ) ]}^{2} + {[ f ( x , y + 1 ) - f ( x , y ) ]}^{2} \}$$

Roberts operator: Grayscale differences of diagonally adjacent pixels are calculated. The sum of squares of grayscale differences between every two diagonally adjacent pixels of four adjacent pixels is calculated as the gradient value of each pixel, and the gradient values of all the pixels are accumulated to form a value of the sharpness evaluation function.

$$F = {\sum }_{x} {\sum }_{y} \{ {[ f ( x + 1 , y + 1 ) - f ( x , y ) ]}^{2} + {[ f ( x + 1 , y ) - f ( x , y + 1 ) ]}^{2} \}$$

Tenengrad function: This function uses a Sobel operator to calculate the gradient values of each pixel in the horizontal and vertical directions. The function is defined as the sum of squares of the gradient values of pixels. In addition, the sensitivity of the function is adjusted by setting a threshold T.

$$F = {\sum }_{x} {\sum }_{y} [ {G}^{2} ( x , y ) ] ( G ( x , y ) > T )$$

where G (x, y) is a gradient at a pixel (x, y);

$$G ( x , y ) = \sqrt{{G}_{x}^{2} ( x , y ) + {G}_{y}^{2} ( x , y )}$$

$${G}_{x}^{2} ( x , y ) and {G}_{y}^{2} ( x , y )$$

are gradient values of the pixel in the horizontal and vertical directions; and

$${G}_{x} ( x , y ) = f ( x , y ) ⊗ {g}_{x}$$

$${G}_{y} ( x , y ) = f ( x , y ) ⊗ {g}_{y}$$

⊗ is a convolution sign, and gₓ and g_{y} are respectively a horizontal template and a vertical template of the Sobel operator.

Gradient filter method: It is also known as a Brenner function, which only needs to calculate the sum of differences between a pixel of interest and pixels that are two pixels away from the pixel of interest on the x-axis, i.e., calculate a second-order degree, thus reducing the amount of calculation.

$$F = {\sum }_{x} {\sum }_{y} \{ {[ f ( x + 2 , y ) - f ( x , y ) ]}^{2} \}$$

Variance function: It shows the dispersion of the grayscale distribution of the image. When the image is out of focus, the variation range of grayscale values is small and the degree of dispersion is low, so the variance is also small. When the image is focused, the variation range of grayscale value is large and the degree of dispersion is high, so the variance is large.

$$F = {\sum }_{x} {\sum }_{y} \{ {[ f ( x + 2 , y ) - μ ]}^{2} \}$$

where μ is an average grayscale value of the image.

$$μ = \frac{1}{MN} {\sum }_{x} {\sum }_{y} f ( x , y )$$

Information entropy-based sharpness evaluation method: In the field of information theory, entropy is an indicator to measure the richness of information. The diversity of the grayscale distribution of focused images may be analyzed using an information entropy evaluation function. When the grayscale values of pixels are widely distributed and significantly different from each other, the entropy value is high. For out-of-focus images, the opposite is true.

$$F = - {\sum }_{g = 0}^{G} {P}_{k} ( g ) {log}_{b} {P}_{k} ( g )$$

where b is generally 2, g represents an image grayscale value, G represents a maximum value of the image grayscale value, k represents a sequence of out-of-focus images, and P(g) represents the probability of occurrence of a grayscale value g in a kth image.

$${P}_{k} ( g ) = \frac{{n}_{g}}{MN}$$

where MN represents the total number of pixels, and n indicates the number of pixels whose grayscale value is g in the kth image.

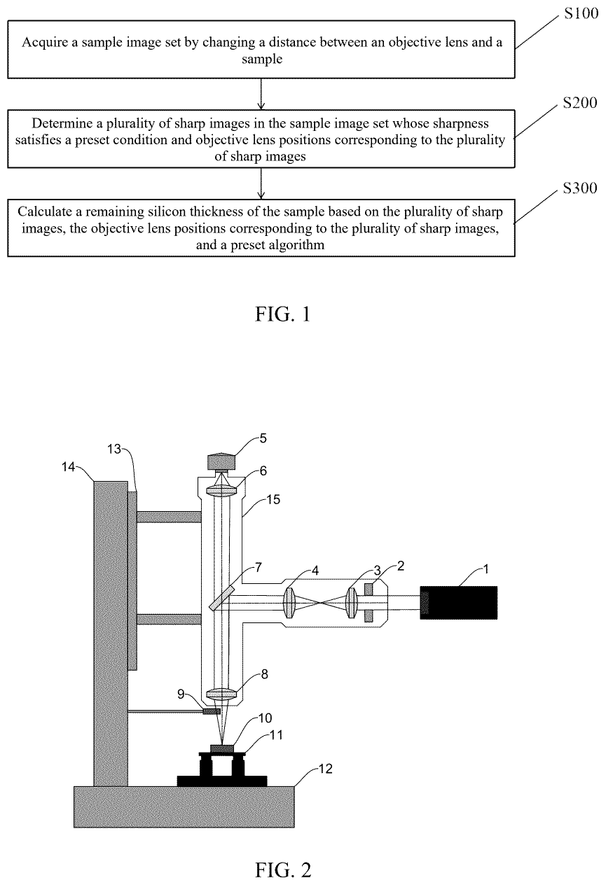

As shown in FIG. 1, an embodiment of the present disclosure provides a method for measuring remaining silicon thickness, which includes the following steps.

In a step of S100, a sample image set is acquired by changing a distance between an objective lens and a sample.

Optionally, the sample image set is formed by light converged onto the sample after passing through the objective lens and a rough-surface silicon wafer in sequence and reflected by the sample to pass through the rough-surface silicon wafer, the objective lens, and an imaging lens in sequence; and the sample includes a smooth surface wafer having one or more cylindrical hole.

For smooth surface wafers and rough surface wafers, the RST is calculated by subtracting a height corresponding to the bottom of a TSV from a height corresponding to the wafer surface. The determination of the surface height of a smooth surface wafer is relatively complicated, while the determination of the surface height of a rough surface wafer is easy. Therefore, the present disclosure mainly designs a method for measuring the remaining silicon thickness of a smooth surface wafer, in which the height of the smooth surface wafer and the height corresponding to the bottom of the TSV are determined through image sampling and analysis, and the remaining silicon thickness of the smooth surface wafer is calculated according to the heights.

Optionally, the light is emitted by a broadband light source including both silicon-transmissive and silicon-non-transmissive spectral bands.

Because the imaging light includes the silicon-transmissive spectral band, the sample image set may include sample images of the interior, surface, and exterior of the wafer. In the present disclosure, the measurement is performed from the back side, such that the problem that light cannot be irradiated to the bottom of TSV structures with a high aspect ratio can be effectively solved. Conventional optical measurement methods are often limited in accurately obtaining depth information of TSV structures with a large depth and high aspect ratio. By the present disclosure, the incident light from the back side can better illuminate the bottom of the TSV, and significantly improve the measurement accuracy.

In a step of S200, a plurality of sharp images in the sample image set whose sharpness satisfies a preset condition and objective lens positions corresponding to the plurality of sharp images are determined.

A sharpness evaluation value dataset is calculated based on the sample image set and a sharpness evaluation function. The sharpness evaluation function includes, but not limited to, an energy gradient function, a Roberts function, a Tenengrad function, a Brenner function, a variance function, a Laplace function, and an information entropy-based sharpness evaluation function.

The plurality of sharp images whose sharpness satisfies the preset condition is acquired based on the sharpness evaluation value dataset and the preset condition. The corresponding objective lens positions are acquired based on the plurality of sharp images.

In some embodiments, the process of acquiring the plurality of sharp images whose sharpness satisfies the preset condition based on the sharpness evaluation value dataset and the preset condition in S200 may be implemented by the following steps.

In a step of S210, a plurality of sharpness evaluation maxima is acquired based on the sharpness evaluation value dataset.

A data trend in the sharpness evaluation value dataset is analyzed, and a plurality of sharpness evaluation maxima in the sharpness evaluation value dataset that conform to a data trend of maxima is obtained. When the sharpness evaluation value corresponding to an image is a maximum, it indicates that the image is a sharp image.

In a step of S220, the plurality of sharp images is acquired based on the plurality of sharpness evaluation maxima.

An analysis is made based on the plurality of sharpness evaluation maxima and corresponding sample images, to select a sharp image of a bottom of the cylindrical hole of the smooth surface wafer, a sharp image of the rough-surface silicon wafer, and a sharp image of a reflected virtual image of the rough-surface silicon wafer.

In a step of S300, a remaining silicon thickness of the sample is calculated based on the plurality of sharp images, the objective lens positions corresponding to the plurality of sharp images, and a preset algorithm.

According to sharp images corresponding to a plurality of key positions and objective lens positions corresponding to the sharp images, an objective lens position of the smooth surface wafer may be determined, and then the remaining silicon thickness of the sample may be calculated according to a preset algorithm.

In some embodiments, the process of calculating a remaining silicon thickness of the sample based on the plurality of sharp images, the objective lens positions corresponding to the plurality of sharp images, and a preset algorithm in S300 may be implemented by the following steps.

In a step of S310, a thickness value of the rough-surface silicon wafer is acquired.

In a step of S320, the remaining silicon thickness of the sample is calculated based on the objective lens position corresponding to the sharp image of the bottom of the cylindrical hole of the smooth surface wafer, the objective lens position corresponding to the sharp image of the rough-surface silicon wafer, the objective lens position corresponding to the sharp image of the reflected virtual image of the rough-surface silicon wafer, the thickness value, and the preset algorithm.

By inserting the rough-surface silicon wafer, and determining the objective lens position corresponding to the surface of the smooth surface wafer according to the sharp image of the rough-surface silicon wafer and the sharp image of the reflected virtual image of the rough-surface silicon wafer, the remaining silicon thickness of the smooth surface wafer can be calculated further according to the objective lens position corresponding to the sharp image of the bottom of the cylindrical hole of the smooth surface wafer.

As shown in FIG. 2, an embodiment of the present disclosure further provides a system for measuring remaining silicon thickness. The system includes a light source 1, an aperture stop 2, a first collimating lens 3, a second collimating lens 4, a camera 5, an imaging lens 6, a beam splitter 7, an objective lens 8, a rough-surface silicon wafer 9, a sample 10, a leveling device 11, a platform 12, a movable guide rail 13, a column 14, and a processor.

The platform 12 is configured for fixing the column 14 and the leveling device 11.

The leveling device 11 is configured for loading a sample.

The column 14 is configured for fixing the movable guide rail 13.

The movable guide rail 13 is configured for fixing the lens cavity 15. The aperture stop 2, the first collimating lens 3, the second collimating lens 4, the camera 5, the imaging lens 6, the beam splitter 7, and the objective lens 8 are included in the lens cavity 15.

Optionally, a speed change rule of the movable guide rail may be set, and the lens cavity is driven to move through the guide rail, so as to further move the objective lens in the system. Because the speed change rule of the movable guide rail can be set according to actual requirements, the position to which the objective lens has moved can be determined in real time by recording the time of movement of the movable guide rail (a distance by which the objective lens moves can be obtained in real time by setting a starting point of the objective lens as a reference point), such that the remaining silicon thickness can be measured.

The processor is configured for implementing the method described above.

Light emitted by the light source 1 passes through the aperture stop 2, the first collimating lens 3, the second collimating lens 4, and the beam splitter 7 in sequence. The light deflected by the beam splitter 7 passes through the objective lens 8, the rough-surface silicon wafer 9, and the sample 10 in sequence, and is reflected by the sample 10 to pass through the rough-surface silicon wafer 9, the objective lens 8, the beam splitter 7, and the imaging lens 6 in sequence and finally enter the camera.

Optionally, the light source is a broadband light source including both silicon-transmissive and silicon-non-transmissive spectral bands.

Further, the system provided by the present disclosure may use visible light and infrared light in combination for measurement, which can not only realize high-resolution imaging of the wafer surface, but also effectively measure the internal structure of the wafer. By such an innovative method, comprehensive depth information can be acquired, thus meeting the requirements of measuring various materials and structures.

According to the system provided by the present disclosure, a sample image set is acquired by changing a distance between an objective lens and a sample, sharpness evaluation is performed on the sample image set, and corresponding sharp images are obtained by screening using a preset condition based on the sharpness evaluation value dataset; and finally, a remaining silicon thickness measurement result can be quickly obtained with high precision through calculation according to the sharp images, objective lens positions corresponding to the sharp images, and a preset algorithm. Different from conventional contact measurement methods, in the present disclosure, the measurement is performed by imaging, thus maintaining the advantages of non-contact detection and avoiding possible damage to the device caused by physical contact. Such a detection method is more suitable for rapid detection in production lines to ensure the safety and integrity of the equipment.

It can be seen that the contents of the above method embodiments also apply to this system embodiment. Functions implemented in this system embodiment are the same as those in the above method embodiments, and this system embodiment can achieve the same beneficial effects as those achieved in the above method embodiments.

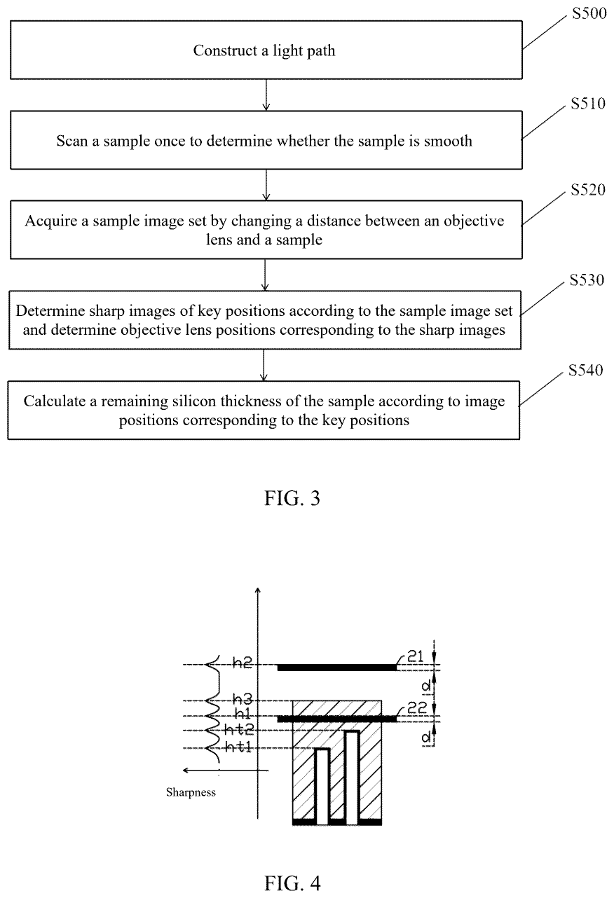

FIG. 3 is a schematic flowchart of another method for measuring remaining silicon thickness according to an embodiment of the present disclosure. The present disclosure further provides another method for measuring remaining silicon thickness. The method is applied to the system for measuring remaining silicon thickness in FIG. 2, and includes the following steps.

In a step of S500, a light path is constructed. The optical path is constructed according to FIG. 2.

Light emitted by the light source passes through the aperture stop, the first collimating lens, the second collimating lens, and the beam splitter in sequence. The light deflected by the beam splitter passes through the objective lens, the rough-surface silicon wafer, and the sample in sequence, and is reflected by the sample to pass through the rough-surface silicon wafer, the objective lens, the beam splitter, and the imaging lens in sequence and finally enter the camera.

In a step of S510, the sample is scanned once to determine whether the sample is smooth.

The objective lens is moved to sample an image of the entire sample once. Whether the surface of the sample wafer is smooth is determined by computer analysis. If the surface of the sample wafer is rough, a corresponding image of the surface of the rough wafer may be directly acquired; otherwise, the sample wafer is a smooth surface wafer.

When the scanning direction is not perpendicular to the wafer surface, the leveling device 11 may be controlled according to image sampling information to compensate for the tilt angle.

In a step of S520, a sample image set is acquired by changing a distance between the objective lens and the sample.

Through the image sampling in S510, an objective lens position corresponding to the bottom of a cylindrical hole of the sample wafer can be determined (if there are a plurality of cylindrical holes, the cylindrical hole closest to the surface of the sample wafer among the cylindrical holes that can be clearly imaged is selected). In practice, during measurement, the objective lens is first moved downward to below the objective lens position corresponding to the bottom of the cylindrical hole of the sample wafer. Then, the objective lens is moved upward at a uniform speed, during which images are collected at a uniform speed to form a sample image set.

Optionally, if the surface of the sample wafer is rough, the rough-surface silicon wafer is removed from the system and then S520 is executed.

Further, the moving speed of the movable guide rail is designed to be uniform, and the lens cavity is driven to move through the guide rail to further cause the objective lens in the system to move at a uniform speed. Because the moving speed of the movable guide rail is designed to be uniform, the position to which the objective lens has moved can be determined in real time by recording the time of movement of the movable guide rail (a distance by which the objective lens moves can be obtained in real time by setting a starting point of the objective lens as a reference point), such that the remaining silicon thickness can be measured.

In a step of S530, sharp images of key positions are determined according to the sample image set, and objective lens positions corresponding to the sharp images are determined.

While the images are acquired at a uniform speed, a sharpness evaluation value of each acquired image is calculated in real time according to the sharpness evaluation function, until a plurality of sharpness evaluation maxima are obtained. Three sharpness evaluation maxima are selected from the plurality of sharpness evaluation maxima, where the three sharpness evaluation maxima respectively correspond to a sharp image of the bottom of the cylindrical hole of the smooth surface wafer, a sharp image of the rough-surface silicon wafer, and a sharp image of a reflected virtual image of the rough-surface silicon wafer. If the surface of the sample wafer is rough, the surface of the sample wafer may be directly imaged. In the measurement, only two sharpness evaluation maxima and images corresponding to the two sharpness evaluation maxima need to be selected, where the images corresponding to the two sharpness evaluation maxima are the sharp image of the surface of the sample wafer and the sharp image of the bottom of the cylindrical hole of the sample wafer.

Further, the rough-surface silicon wafer is self-made and can be used repeatedly. A pattern on the surface of the rough-surface silicon wafer is known, so the sharp images corresponding to the plurality of sharpness evaluation maxima can be selected by analyzing image information, to determine a sharp image of the rough-surface silicon wafer and a sharp image of the reflected virtual image of the rough-surface silicon wafer.

In a step of S540, a remaining silicon thickness of the sample is calculated according to image positions corresponding to the key positions.

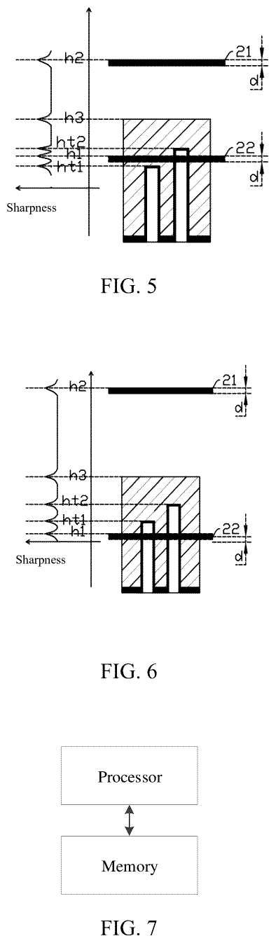

When the surface of the sample wafer is smooth, a positional relationship between the reflected virtual image of the rough-surface silicon wafer and the bottom of the cylindrical hole includes three cases shown in FIG. 4 to FIG. 6, i.e., the virtual image of the rough-surface silicon wafer is located above the bottoms of all the cylindrical holes, the virtual image of the rough-surface silicon wafer is located between the bottoms of the cylindrical holes, and the virtual image of the rough-surface silicon wafer is located below the bottoms of all the cylindrical holes.

In any of the three cases, real and virtual images of the rough-surface silicon wafer satisfy the law of plane mirror imaging, and the imaging of the rough-surface silicon wafer is realized through reflection by the smooth surface of the sample wafer. Therefore, the objective lens position corresponding to the smooth surface of the sample wafer is obtained according to the objective lens positions corresponding to the real and virtual images of the rough-surface silicon wafer.

The objective lens position corresponding to the smooth surface of the sample wafer is calculated using the following formula:

$$h 3 = ( h 2 - h 1 - d ) / 2$$

where d is the thickness of the rough-surface silicon wafer, h1 is the objective lens position corresponding to the sharp image of the rough-surface silicon wafer, h2 is the objective lens position corresponding to the self-made silicon wafer, and h3 is the objective lens position corresponding to the smooth surface of the sample wafer.

Further, the remaining silicon thickness of the sample may be calculated using the following formula:

$$remaining silicon thickness Hrst = ( h 2 - h 1 - d ) / 2 - htx$$

where d is the thickness of the rough-surface silicon wafer, h1 is an objective lens position corresponding to an image of the self-made silicon wafer, h2 is the objective lens position corresponding to the sharp image of the reflected virtual image of the rough-surface silicon wafer, h3 is the objective lens position corresponding to the smooth surface of the sample wafer, and htx is the objective lens position corresponding to the bottom of the cylindrical hole (x=1, 2, 3 . . . ).

Further, during measurement, the system provided by the present disclosure can capture an image of the bottoms of a plurality of cylindrical holes, and can automatically calculate the number of cylindrical holes in the image (where the bottoms of a plurality of cylindrical holes may be located at the same objective lens position).

In accordance with another aspect of the present disclosure, when the surface of the sample wafer is rough, there is no need to use a self-made rough-surface silicon wafer; and the remaining silicon thickness of the sample may be calculated using the following formula:

$$remaining silicon thickness Hrst = H - htx$$

where H is the objective lens position corresponding to the sharp image of the surface of the rough surface wafer, and htx is the objective lens position corresponding to the bottom of the cylindrical hole (x=1, 2, 3 . . . ).

As shown in FIG. 7, an embodiment of the present disclosure further provides a device for measuring remaining silicon thickness, including:
at least one processor; and
at least one memory, configured for storing at least one program,
where the at least one program, when executed by the at least one processor, causes the at least processor to implement the method steps described in the above method embodiments.

The memory, as a non-transitory computer-readable storage medium, may be configured for storing a non-transitory software program and a non-transitory computer-executable program. The memory may include a high-speed random access memory, and may also include a non-transitory memory, e.g., at least one magnetic disk storage device, a flash memory device, or other non-transitory solid-state storage device. In some implementations, the memory may include remote memories located remotely from the processor, and the remote memories may be connected to the processor via a network. Examples of the network include, but not limited to, the Internet, an intranet, a local area network, a mobile communication network, and combinations thereof.

It can be seen that the contents of the embodiments of the method of the present disclosure are applicable to this device embodiment. Functions implemented in this device embodiment are the same as those in the above method embodiments, and this device embodiment can achieve the same beneficial effects as those achieved in the above method embodiments.

In addition, an embodiment of the present disclosure provides a computer program product or a computer program stored in a computer-readable storage medium, where the computer program product or the computer program, when read from the computer-readable storage medium by a processor of a computer device, causes the computer device to implement the method described above.

An embodiment of the present disclosure provides a computer-readable storage medium, having a processor-executable program stored thereon. The processor-executable program, when executed by a processor, causes the processor to implement the method described above. The contents of the above method embodiments also apply to this storage medium embodiment. Functions implemented in this storage medium embodiment are the same as those in the above method embodiments, and this storage medium embodiment can achieve the same beneficial effects as those achieved in the above method embodiments.

It can be understood that all or some of the steps in the methods disclosed above and the functional modules/units in the system and the apparatus can be implemented as software, firmware, hardware, and appropriate combinations thereof. Some or all physical components may be implemented as software executed by a processor, such as a central processing unit, a digital signal processor, or a microprocessor, or as hardware, or as an integrated circuit, such as an application-specific integrated circuit. Such software may be distributed on a computer-readable medium, which may include a computer storage medium (or non-transitory medium) and a communication medium (or transitory medium). As is known to those having ordinary skills in the art, the term “computer storage medium” includes volatile and nonvolatile, removable and non-removable media implemented in any method or technology for storage of information (such as computer-readable instructions, data structures, program modules, or other data). The computer storage medium includes, but not limited to, a random access memory (RAM), a read-only memory (ROM), an electrically erasable programmable read-only memory (EEPROM), a flash memory or other memory technology, a compact disc read-only memory (CD-ROM), a digital versatile disc (DVD) or other optical storage, a cassette, a magnetic tape, a magnetic disk storage or other magnetic storage device, or any other medium which can be used to store the desired information and which can be accessed by a computer. In addition, as is known to those having ordinary skills in the art, the communication medium typically includes computer-readable instructions, data structures, program modules, or other data in a modulated data signal such as a carrier or other transport mechanism, and can include any information passing medium.

Although some embodiments of the present disclosure have been described above, the present disclosure is not limited to the implementations described above. Those having ordinary skills in the art can make various equivalent modifications or replacements without departing from the protection scope of the present disclosure. Such equivalent modifications or replacements fall within the scope defined by the claims of the present disclosure.

What is claimed is:

1. A method for measuring remaining silicon thickness, comprising:
acquiring a sample image set by changing a distance between an objective lens and a sample, wherein the sample image set is formed by light converged onto the sample after passing through the objective lens and a rough-surface silicon wafer in sequence and reflected by the sample to pass through the rough-surface silicon wafer, the objective lens, and an imaging lens in sequence; and the sample comprises a smooth surface wafer having one or more cylindrical hole;
determining a plurality of sharp images in the sample image set whose sharpness satisfies a preset condition and objective lens positions corresponding to the plurality of sharp images; and
calculating a remaining silicon thickness of the sample based on the plurality of sharp images, the objective lens positions corresponding to the plurality of sharp images, and a preset algorithm.

2. The method of claim 1, wherein the determining a plurality of sharp images in the sample image set whose sharpness satisfies a preset condition and objective lens positions corresponding to the plurality of sharp images comprises:
calculating a sharpness evaluation value dataset based on the sample image set and a sharpness evaluation function;
acquiring the plurality of sharp images whose sharpness satisfies the preset condition based on the sharpness evaluation value dataset and the preset condition, wherein the plurality of sharp images whose sharpness satisfies the preset condition comprises a sharp image of a bottom of the cylindrical hole of the smooth surface wafer, a sharp image of the rough-surface silicon wafer, and a sharp image of a reflected virtual image of the rough-surface silicon wafer; and
acquiring the corresponding objective lens positions based on the plurality of sharp images.

3. The method of claim 2, wherein the acquiring the plurality of sharp images whose sharpness satisfies the preset condition based on the sharpness evaluation value dataset and the preset condition comprises:
acquiring a plurality of sharpness evaluation maxima based on the sharpness evaluation value dataset; and
acquiring the plurality of sharp images based on the plurality of sharpness evaluation maxima.

4. The method of claim 2, wherein the calculating a remaining silicon thickness of the sample based on the plurality of sharp images, the objective lens positions corresponding to the plurality of sharp images, and a preset algorithm comprises:
acquiring a thickness value of the rough-surface silicon wafer; and
calculating the remaining silicon thickness of the sample based on the objective lens position corresponding to the sharp image of the bottom of the cylindrical hole of the smooth surface wafer, the objective lens position corresponding to the sharp image of the rough-surface silicon wafer, the objective lens position corresponding to the sharp image of the reflected virtual image of the rough-surface silicon wafer, the thickness value, and the preset algorithm.

5. The method of claim 4, wherein the preset algorithm comprises:
$$Hrst = ( h 2 + h 1 - d ) / 2 - ht$$
wherein Hrst is the remaining silicon thickness of the sample, h1 is the objective lens position corresponding to the sharp image of the rough-surface silicon wafer, h2 is the objective lens position corresponding to the sharp image of the reflected virtual image of the rough-surface silicon wafer, d is the thickness value, and ht is the objective lens position corresponding to the sharp image of the bottom of the cylindrical hole of the smooth surface wafer.

6. A system for measuring remaining silicon thickness, comprising a camera, a lens cavity, a light source, a rough-surface silicon wafer, a leveling device, a platform, a column, a movable guide rail, and a processor, wherein:
the platform is configured for fixing the column and the leveling device;
the leveling device is configured for loading a sample;
the column is configured for fixing the movable guide rail;
the movable guide rail is configured for fixing the lens cavity;
the processor is configured for implementing the method of claim 1;
the lens cavity comprises an aperture stop, a collimating lens unit, a beam splitter, an objective lens, and an imaging lens;
light emitted by the light source passes through the aperture stop, a first collimating lens, a second collimating lens, and the beam splitter in sequence; and the light deflected by the beam splitter passes through the objective lens, the rough-surface silicon wafer, and the sample in sequence, and is reflected by the sample to pass through the rough-surface silicon wafer, the objective lens, the beam splitter, and the imaging lens in sequence and finally enter the camera.

7. The system of claim 6, wherein the light source is a broadband light source comprising both silicon-transmissive and silicon-non-transmissive spectral bands.

8. The system of claim 6, wherein the rough-surface silicon wafer comprises a grid pattern, the grid pattern comprising bar, square and circular shapes.

9. A device for measuring remaining silicon thickness, comprising:
at least one processor; and
at least one memory, configured for storing at least one program,
wherein the at least one program, when executed by the at least one processor, causes the at least processor to perform the method of claim 1.

10. A non-transitory computer-readable storage medium, having a processor-executable program stored therein, wherein the processor-executable program, when executed by a processor, causes the processor to perform the method of claim 1.
